(19) United States
(12) Patent Application Publication
(10) Pub. No.: US 2008/0036308 A1
(43) Pub. Date: Feb. 14, 2008

(54) Magnetically Driven Reciprocating System And Method

(76) Inventor: Daniel Schlesinger, Beniamina (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(21) Appl. No.: 11/692,950

(22) Filed: Mar. 29, 2007

Related U.S. Application Data
(60) Provisional application No. 60/822,237, filed on Aug. 13, 2006.

(51) Int. Cl. H01L 41/09

(52) U.S. Cl. 310/26

(57) ABSTRACT

A magnetically driven reciprocating power output system including: at least one first electromagnet having a direction of elongation defining an axial direction, having a first end and a second end, and having an elongated opened core extending from the first end to the second end, the core having an axis of symmetry substantially coaxial with the axial direction; a control unit adapted to provide a first power input to the first electromagnet and adapted to cause the electromagnet to have a time-varying first magnetic field with a first polarity directed in substantially the axial direction; at least one stationary body having a second magnetic field with a second polarity directed in substantially the axial direction and configured substantially coaxially with the core region at the first end; at least one reciprocating ferromagnetic body configured substantially coaxially with the core, and not extending completely outside of the core at the second end, adapted to have a second magnetic field in response to the first magnetic field, the body displaceable axially in response to the first and second magnetic fields; and a transducer unit mechanically connected to the reciprocating body and adapted to convert a displacement of the reciprocating body to a power output.

The current application claims the benefit of U.S. Provisional Patent Application No. 60/822,237, filed Aug. 13 2006, whose disclosure is incorporated herein by reference.

### FIELD AND BACKGROUND OF THE INVENTION

The present invention relates to a magnetically driven reciprocating system and method and, in particular, it concerns a magnetically driven reciprocating system and method that provide output power.

Conventional rotary electric motor or actuator systems typically convert electrical energy into mechanical energy. Examples of electric motors are those found in household appliances such as: fans: exhaust fans: fridges: washing machines: pool pump; and fan-forced ovens-to name a very few.

Most rotary electric motors work by electromagnetism (although there are motors based on other electromechanical phenomena, such as electrostatic forces and piezoelectric effect). The fundamental principle upon which electromagnetic motors are based is that there is a mechanical force on any current-carrying wire contained within a magnetic field. The force, described by the Lorentz force law, is normal to both the conductor and the magnetic field. Rotary motors as known in the art are configured to take advantage of this effect.

A linear motor is essentially a multi-phase AC electric motor that has had its stator (i.e. the stationary part of the motor) “unrolled” so that instead of producing a torque (rotation), it produces a linear force along its length The most common mode of operation is as a Lorenz-type actuator, in which the applied force is linearly proportional to the current and the magnetic field, according to the aforementioned Lorentz force law.

Many conventional electromagnetic motors, such as those mentioned hereinabove, function with limited efficiencies as a result of various factors including, but not limited to structure, operating speed and conditions, torque, and material composition. Very few, if any, of the devices mentioned hereinabove are typified by reciprocating motion.

There is therefore a need for a scalable magnetic reciprocating system which can operate with high efficiency and/or can generate power.

### SUMMARY OF THE INVENTION

The present invention is a magnetic reciprocating system and method that provide output power. According to the teachings of the present invention there is provided, a magnetically driven reciprocating power output system including: at least one first electromagnet having a direction of elongation defining an axial direction, having a first end and a second end, and having an elongated opened core extending from the first end to the second end, the core having an axis of symmetry substantially coaxial with the axial direction; a control unit adapted to provide a first power input to the first electromagnet and adapted to cause the electromagnet to have a time-varying first magnetic field with a first polarity directed in substantially the axial direction; at least one stationary body having a second magnetic field with a second polarity directed in substantially the axial direction and configured substantially coaxially with the core region at the first end; at least one reciprocating ferromagnetic body configured substantially coaxially with the core, and not extending completely outside of the core at the second end, adapted to have a second magnetic field in response to the first magnetic field, the body displaceable axially in response to the first and second magnetic fields; and a transducer unit mechanically connected to the reciprocating body and adapted to convert a displacement of the reciprocating body to a power output Preferably, the power output is not less than the first power input Most preferably, the transducer unit further includes a mechanical energy buffer adapted to non-simultaneously store the power output and to return a second power input.

Typically, the transducer unit is further adapted to sense the power output, displacement, and velocity of the reciprocating body. Most typically, the control unit is further adapted to control a plurality of time-varying electrical pulses to provide the first power input based on data indicative from the transducer unit of the sensed power output, displacement, and velocity of the reciprocating body. Most preferably, the control unit is further adapted to control the first power input to maximize the power output.

Most preferably, the stationary body is substantially permanently magnetic. Typically, the stationary body is ferromagnetic and the second magnetic field is present in response to the first magnetic field. Most typically, the stationary body is a non-powered electromagnet.

Preferably, the stationary body is a powered electromagnet electromagnetic and the second field is maintained substantially constant or second field is varied in coordination with variations of the first magnetic field. Most preferably, the first electromagnet and the reciprocating ferromagnetic body are fixed in a common housing, and wherein the housing is displaceable axially in response to the first and second magnetic fields.

According to the teachings of the present invention there is further provided a method of operating a magnetic reciprocating generating system including the steps of taking at least one first electromagnet having a direction of elongation defining an axial direction, having a first end and a second end, and having an elongated opened core extending from the first end to the second end, the core having an axis of symmetry substantially coaxial with the axial direction; providing a first power input to the first electromagnet with a control unit and causing the electromagnet to have a time-varying first magnetic field with a first polarity directed in substantially the axial direction; configuring at least one stationary body substantially coaxially with the core region at the first end, the stationary body having a second magnetic field with a second polarity directed in substantially the axial; configuring at least one reciprocating ferromagnetic body substantially coaxially with the core, and not extending completely outside of the core at the second end, having a second magnetic field in response to the first magnetic field, the body displaced axially in response to the first and second magnetic fields; and connecting a transducer unit mechanically to the reciprocating body, the transducer unit converting a displacement of the reciprocating body to a power output.

Most preferably, the transducer unit further includes a mechanical energy buffer unit which non-simultaneously stores power output and to return a second power input. Preferably, the transducer unit further senses the power output, displacement, and velocity of the reciprocating body. Typically, a plurality of time-varying electrical pulses is controlled by the control unit to provide the first power input based on data indicative from the transducer unit of the sensed power output, displacement, and velocity of the reciprocating body. Most typically, the power output is maximized by the control unit controlling the first power input

Preferably, the stationary body is substantially permanently magnetic. Most preferably, the stationary body is ferromagnetic and the second magnetic field is present in response to the first magnetic field.

### BRIEF DESCRIPTION OF THE DRAWINGS

The invention is herein described, by way of example only, with reference to the accompanying drawings, wherein:

FIGS. 1A and 1B are schematic representations of a magnetically driven reciprocating power output system including a housing, a toroidal shaped electromagnet configured within the housing, and a ferromagnetic body positioned within the open space of electromagnet, in accordance with an embodiment of the present invention;

FIGS. 2A and 2B are schematic representations of a magnetically driven reciprocating power output system similar to the system shown in FIGS. 1A and 1B, in accordance with an embodiment of the present invention;

FIGS. 3A and 3B schematic representations of a magnetically driven reciprocating power output system similar to the system shown in FIGS. 1A and 1B, in accordance with an embodiment of the present invention;

FIG. 4 is a graph showing force versus displacement for a series of experiments; and

FIGS. 5 and 6 are output of an oscilloscope and a schematic diagram, respectively, of an additional experimental setup.

### DESCRIPTION OF PREFERRED EMBODIMENTS

The present invention includes a magnetic reciprocating system and method that provides output power.

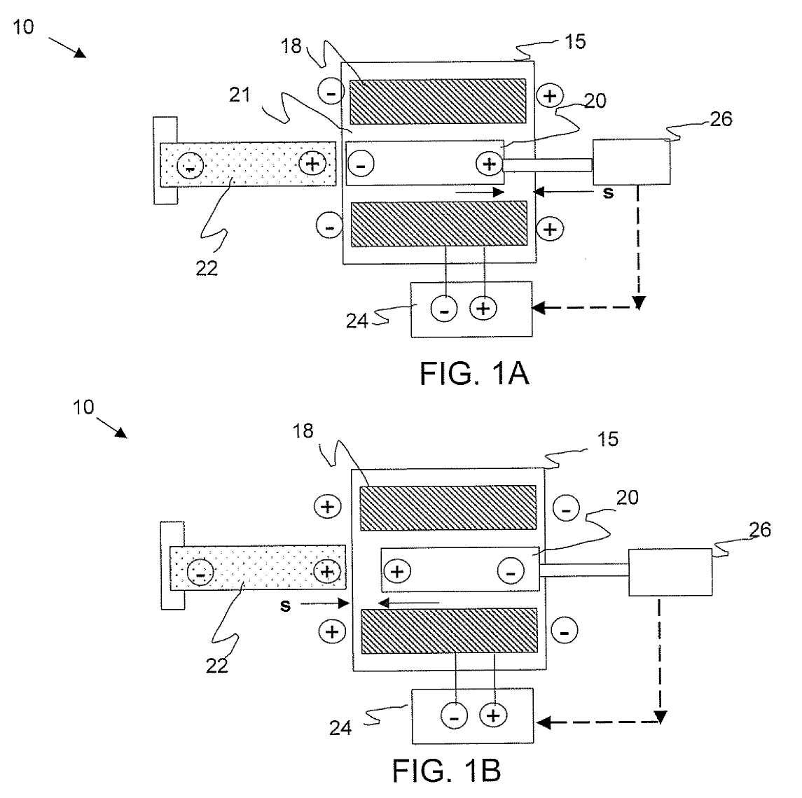

Reference is now made to FIGS. 1A and 1B, which are schematic representations of a magnetically driven reciprocating power output system 10 including a housing 15, a toroidal shaped electromagnet 18 configured within the housing, and a ferromagnetic body 20 positioned within an open core 21 of electromagnet 18, in accordance with an embodiment of the present invention. The term “electromagnet” noted hereinbelow in the specification and in the claims which follow refers to any inductor that creates a magnetic field and subsequent magnetic force due to an electric current. Electromagnet 18 is typically an “open core” electromagnet of any suitable construction; however a solid core electromagnet that may be bored or otherwise modified to allow the ferromagnetic body to be configured substantially in open core 21 is also suitable. Open core 21 typically has an axis of symmetry (not shown in the figure) defining an axial direction of the system. Electromagnet 18 is fixed within the housing and ferromagnetic body 20 may translate axially within the open core. The magnetic polarities of electromagnet 18 and of ferromagnetic body 20 are aligned axially, as shown in the figures and as are further described hereinbelow. Optionally or alternatively, electromagnet 18 may represent more than one electromagnets having a similar configuration as described hereinabove and arranged substantially coaxially (not shown in the figure) to allow ferromagnetic body 20 to translate within the open cores.

A stationary body 22 is configured coaxially with the open core, in close proximity to electromagnetic 18, but outside of the housing and outside of core 21. In embodiments of the present invention, stationary body is alternatively or optionally: ferromagnetic with ideally no remanence, meaning that it retains no magnetization when the driving magnetic field of electromagnet 18 ceases; permanently magnetized (with high remanence); or electromagnetic—either activated or not activated when electromagnet 18 is activated. The magnetic polarity of stationary body 22 is aligned axially and is non-varying when stationary body is not an activated electromagnet (no electric current is flowing in the electromagnet) as shown by the non-varying “+” and “−” notations in the figures.

In the case where stationary body 22 is an electromagnet, the overall function and configuration of stationary body 22 is similar to that of electromagnet 18, and only the core of stationary body 22 is represented in the figure. When stationary body 22 is an activated electromagnet, its polarity and may be time-varying in a manner similar to that described for electromagnet 18 hereinbelow. Alternatively or optionally, stationary body 22 may be an electromagnet which is not activated, in which case the core of the stationary body functions essentially similarly to that of the ferromagnetic body as described hereinabove.

A control unit 24 controls the power input to electromagnet 18, and causes the magnetic polarity to change with time. The terms “power input” and “power output” noted hereinbelow in the specification and in the claims which follow refer to electrical or mechanical power, typically expressed in watts. In an embodiment of the current invention, the control unit controls power pulses to the electromagnet by controlling the pulse frequency (number of power pulses per second, for example) and pulse duration (measured in milliseconds, for example) of power pulses. In one embodiment, control unit 24 supplies time-variable power pulses, as known in the art (such as, but not limited to, Pulse Wave Modulation methods) to alternately change the direction of magnetic polarity of the electromagnet, as shown by the alternate “+” and “−” notations in FIGS. 1A and 1B. Alternatively or optionally, control unit 24 supplies time-variable power pulses, as known in the art (such as but not limited to Pulse Wave Modulation methods) to alternately power and de-energize the electromagnet, thereby creating and ceasing a magnetic polarity in only one direction (not shown in the figures). As noted previously and as further noted hereinbelow, the magnetic polarity of ferromagnetic body 20 reacts to that of the electromagnet.

In the case where stationary body 22 is an activated electromagnet, as noted hereinabove, control unit 24 may additionally control the power input to the stationary body to enhance reciprocation of ferromagnetic body 20, as described hereinbelow.

In FIG. 1A, it can be seen that when the magnetic polarities of the ferromagnetic body and the stationary body are of opposing signs, ferromagnetic body 20 is attracted to the stationary body and moves a displacement “s” towards stationary body 22. In FIG. 1B, it can be seen that when the magnetic polarities of the ferromagnetic body and the stationary body are of matching signs, ferromagnetic body 20 is repelled and moves a displacement “s” away from stationary body 22. Controller unit 24 controls and varies the power input to electromagnet 18 (and of stationary body 22, when applicable) as described hereinabove so that ferromagnetic body 20 reciprocates axially a displacement “s” towards and away from stationary body 22. In addition to variations in polarities of magnetic fields within the system, reciprocating movement of the ferromagnetic body may be enhanced and/or aided by means of mechanical energy, as described hereinbelow.

A transducer unit 26, having a mechanical connection to ferromagnetic body 20, as shown, serves to transduce mechanical energy from ferromagnetic body 20 as it reciprocates within the open core, as described hereinbelow. In one embodiment of the current invention, transducer unit 26 takes the form of a crank connected to a flywheel mounted on a shaft, which in turn drives an additional element, such as an electric generator (not shown in the figure). The flywheel serves to alternately store and return mechanical energy from and back to the ferromagnetic body, with excess mechanical energy transduced to electricity in the generator. Movement of the shaft in the transducing unit may be sensed, as known in the art, using encoders, for example, and information indicative of movement of the ferromagnetic body is fed back to the controller unit (as indicated by the dotted line in FIGS. 1A and 1B). In this way, controller unit 24 controls time variations of power input to the electromagnet to optimize movement of the ferromagnetic body and/or optimize output power of the system. In other embodiments of the current invention, transducer unit 26 may include other components, such as, but not limited to mechanical, electrical, thermal, chemical, and hydraulic components, which may all similarly store and/or transduce energy, while providing feedback to controller unit 24.

In embodiments of the current invention, electromagnet 18 ideally exhibits no hysteresis, meaning that the magnetic field of the electromagnet instantaneously develops and ceases when power is applied and stopped, respectively. Similarly, ferromagnetic body 20 ideally exhibits no remanence, meaning that body 20 retains no magnetization when the driving magnetic field of electromagnet 18 ceases. In one embodiment of the current invention, body 20 is made from steel; however other materials that exhibit mechanical stability and that can acquire a magnetic field and exhibit low magnetic hysteresis, as described hereinabove, are suitable.

Exemplary electromagnets suitable to operated as electromagnet 18 are seen at the website http://www.mannel-magnet.info/en_round.php of Mannel Magnet Technik GbR, Tente 3, 42859 Remscheid, Germany, whose disclosure is incorporated herein by reference.

Experiments, described hereinbelow, were performed to determine and to demonstrate various levels of operation, including input and output work of magnetically driven reciprocating power output system 10.

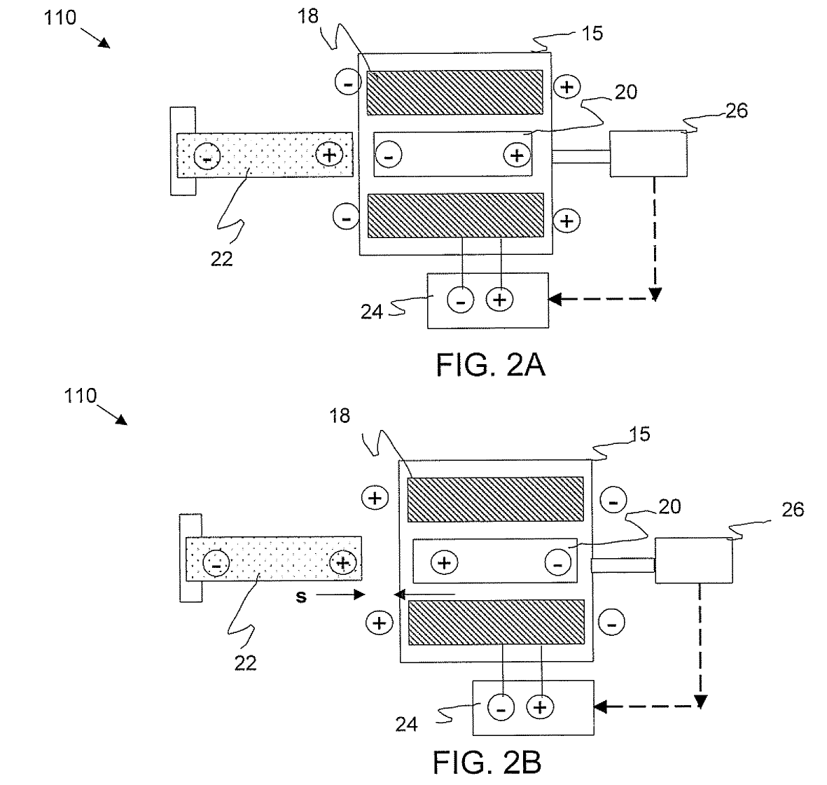

Reference is now made to FIGS. 2A and 2B, which are schematic representations of a magnetically driven reciprocating power output system 110 similar to the system shown in FIGS. 1A and 1B, in accordance with an embodiment of the present invention. Apart from differences described below, magnetically driven reciprocating power output system 110 is generally similar to operation of magnetically driven reciprocating power output system 10 as shown in FIGS. 1A and 1B, so that elements indicated by the same reference numerals are generally identical in configuration and operation. In system 110, the electromagnet and ferromagnetic body are fixed within housing 15 and the housing reciprocates by a displacement “s” to and from stationary body 22. Transducer unit 26 is connected to the housing and functions in similar fashion as described hereinabove.

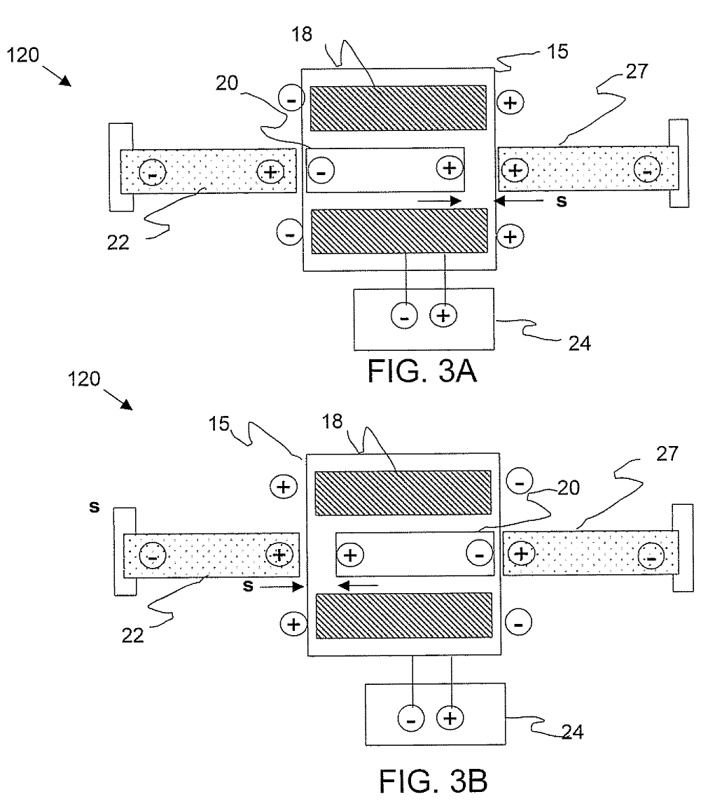

Reference is now made to FIGS. 3A and 3B, which are schematic representations of a magnetically driven reciprocating power output system 120 similar to the system shown in FIGS. 1A and 1B, in accordance with an embodiment of the present invention. Apart from differences described below, magnetically driven reciprocating power output system 120 is generally similar in operation to magnetically driven reciprocating power output system 10 as shown in FIGS. 1A and 1B, so that elements indicated by the same reference numerals are generally identical in configuration and operation. In system 120, a second stationary body 27 is configured coaxially with the open core, in close proximity to electromagnetic 18, but outside of the housing and outside of core 21 and in opposition to stationary body 22.

In embodiments of the present invention, stationary bodies 22 and 27 are alternatively or optionally: ferromagnetic with ideally no remanence, meaning that they retain no magnetization when the driving magnetic field of electromagnet 18 ceases; permanently magnetized (with high remanence); or electromagnetic. When not an electromagnet that is activated, the magnetic polarity of stationary body 27 is aligned axially and is non-varying, as shown by the non-varying “+” and “−” notations in the figures. Furthermore, stationary body 27 may be an electromagnetic and may be operated similarly to the operation described hereinabove for stationary body 22, when stationary body 22 is an activated electromagnet. Although not shown in FIGS. 3A and 3B, system 120 includes transducer unit 26 which functions as described in FIGS. 2A and 2B for system 110, hereinabove.

Another embodiment of system 120 of the current invention includes a configuration with the electromagnet and ferromagnetic body fixed inside the housing 15 and the entire housing reciprocating, similarly to that described in FIGS. 2A and 2B for system 110, hereinabove.

Another embodiment of systems 10 and 120 additionally or optionally includes ferromagnetic body comprising two pieces (not shown in the figures), with one piece being maintained stationary substantially within the core and the second piece reciprocating, as described hereinabove.

Experimental Work and Results

Measurements and calculations of the forces, work, timing, and power were made from experimental setups modeling system 10 (as described hereinabove in FIGS. 1A and 1B]. Characteristics of components of system 10 and other components used for the experiment were:
Electromagnet: Industrial celluloid magnet having input of 45 W, length=80 mm, core diameter=25 mm, rated magnetic force of 60 kg.
Two Paramagnetic bodies: each with diameter=22 mm, length=80 mm, material: soft steel, ST37. The two bodies served to model the reciprocating body of system 10. Relative displacements of one or both of the paramagnetic bodies were measured, as described hereinbelow.
Calibrated springs to measure force: length approximately 200 mm, with spring constant of k=1.1 kg/mm
Strain gauge, manufacturer: Vishay, max. rated 350 kg
Control unit: Power supply 12 VDC, max 4 A, typical operation at 2 A.
Oscilloscope: Gould 475

Note: Had a ferromagnetic material been used in the experiments—instead of the paramagnetic material noted above—it is very reasonable to assume that results would have been substantially improved, as noted hereinbelow.

Objectives of experimental work were to:

1. Determine the maximum forces operating on the paramagnetic material;

2. Provide a measurement of the system's mechanical output work; and

3. Measure of the electrical energy input to obtain the work output. Each of the three objectives and specific experimentation are described in greater detail hereinbelow.

Maximum Forces
1. The two steel paramagnetic bodies were inserted, touching each other at the center point within the electromagnetic core.
2. Each body was fitted with a spring which was attached to a displacement-measurable fixture. The electromagnet was powered at 12 VDC and 2 A and the two bodies were attracted to each other by magnetic force, with the springs having no elongation.
3. The two bodies were then separated by controllably pulling the springs The spring elongation was recorded, yielding a value of the force necessary to counteract and pull the bodies away from one another while they were in the magnetic field of the electromagnet.
4. The measured elongation of the springs was approximately 12 cm. Applying the spring constant of the springs, as noted above, the attractive force was calculated as approximately 60 kg.

Output Work
1. The springs were detached from the bodies and the bodies were again inserted, touching and centered into the core of the magnet, as in step one hereinabove One body was fixed. The second body could move freely axially out of the core. A strain gauge was connected to the end of the second body and a the strain gauge was mechanically connected with an apparatus, which could apply a controlled pulling force acting to separate the bodies.
2. The electromagnet was activated and the apparatus was activated to pull the second body. A separation force was measured based on the strain gague output. The second body moved a given displacement “s” from the other stationary body. Force values were recorded for various “s” values.

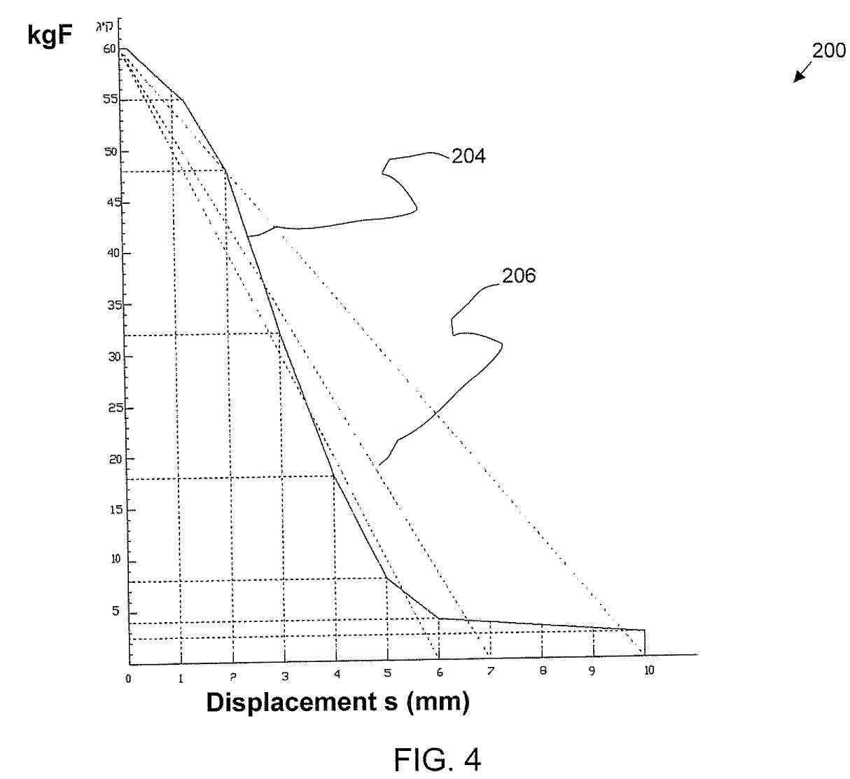

Reference is now made to FIG. 4, which is a graph 200 showing force (in kgF) versus displacement “s” (mm) for the series of experiments as described in step 2, hereinabove. The area under line 204 represents the integral of the force-versus-displacement function, evaluated from the maximum force (60 kg) to minimum force (4 kg). The integral may also be expressed as the mechanical work of the ferromagnetic body. Representative chord 206 on the graph, connecting the values of 60 kg and 7 mm on the respective axes, gives a reasonable linear approximation of line 204, with the areas under chord 206 and under line 204 being approximating equal. The work was calculated as approximately 2.35 Joules.

An additional series of experiments was performed with one body fixed and the second body mechanically connected to a crank arm, which in turn was connected to a shaft upon which a flywheel was mounted. The flywheel had a mass of approximately 10 kg. The work output of the flywheel was measured at one rotation equal to 1.3 Joule. It was further measured that one pulse of the electromagnet yielded a movement of the second body, causing 3 revolutions of the flywheel. The work output of the body was therefore calculated at 1.3×3=4.2 Joule, not taking into account any friction.

Electrical Energy Input

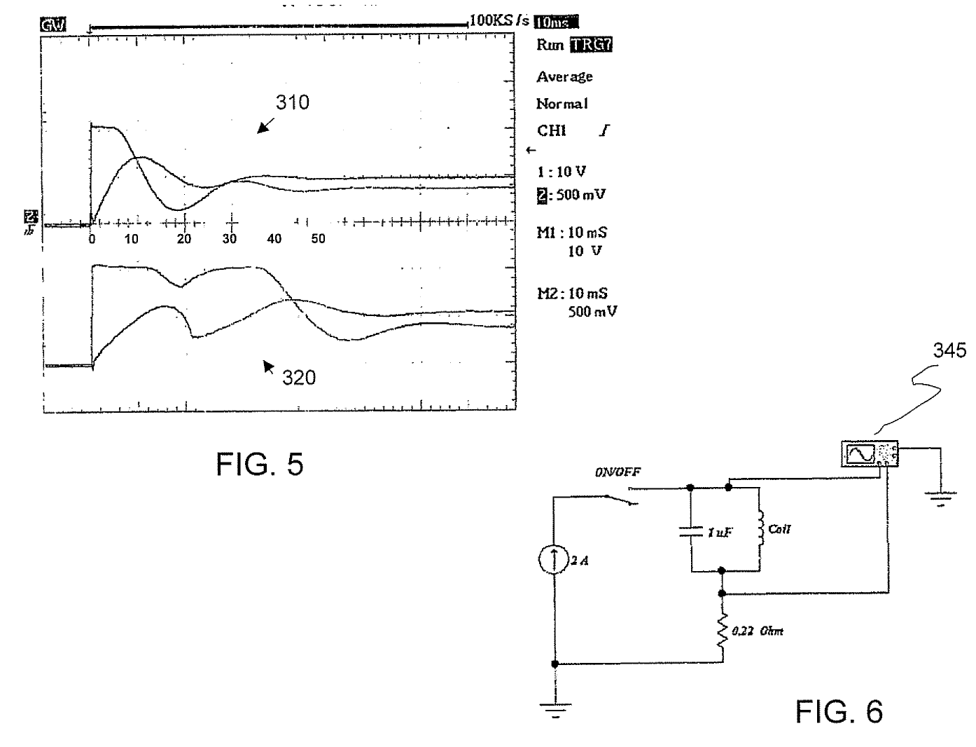

Experimental measurements were made using the bodies and setup as described hereinabove. Reference is now made to FIGS. 5 and 6 which are output of an oscilloscope and a schematic diagram, respectively, of an experimental setup used for the electrical energy input determination. The experimental setup allowed the integrated energy input of an electrical pulse to the electromagnet to be measured for body displacements of 30 mm and 10 mm with respective sets of voltage and current response curves 310 and 320, as indicated in FIG. 5. Response curve set 320, reflecting a typical body displacement of 10 mm was of primary interest. The time scale is indicated in milliseconds from 0, 10, 20, . . . , 50 milliseconds in a horizontal axis in FIG. 5.

Oscilloscope 345 was connected to the electromagnet, indicated as “coil” in FIG. 6. The stationary body was located with its end centered within the electromagnetic core and the moving body was positioned 10 mm away from the center point. The oscilloscope was configured to measure the time response of the electromagnet and the time the moving body contacted the stationary body. A time response was measured as approximately 30 milliseconds.

The input energy may be calculated by taking the 45 W nominal power input and dividing it by 30 milliseconds, yielding 1.5 Joule.

Intermediate Conclusion

Using the values obtained hereinabove: an energy input of 1.5 Joule and a work output of 4.2 Joule, and not taking any other losses into account, there appears to be a significant energy margin “created” by the system. No other losses were measured in the experimental work. An assumption was made of an energy loss due to friction, reducing the work output to approximately 2.3 Joule.

As a result, an intermediate conclusion from the experimental work was that the system, having an approximate energy input of 1.5 Joule and an approximate work output (including friction losses) of 2.3 Joule was, at the least, highly energy efficient, as no other explanation could be made regarding the aforementioned energy margin.

Future Experimentation

Additional experiments are planned using a much larger scaled electromagnet, having approximately 1,000 kg magnetic force, based on an input power of approximately only 37 W. Additional experiments will utilize ferromagnetic bodies, and not paramagnetic bodies as used in previous experiments described hereinabove. Therefore, it is anticipated that the additional experiments will yield even better results regarding energy efficiency.

It will be appreciated that the above descriptions are intended only to serve as examples, and that many other embodiments are possible within the scope of the present invention as defined in the appended claims.

What is claimed is:

1. A magnetically driven reciprocating power output system comprising:
at least one first electromagnet having a direction of elongation defining an axial direction, having a first end and a second end, and having an elongated opened core extending from the first end to the second end, the core having an axis of symmetry substantially coaxial with the axial direction;
a control unit adapted to provide a first power input to the first electromagnet and adapted to cause the electromagnet to have a time-varying first magnetic field with a first polarity directed in substantially the axial direction;
at least one stationary body having a second magnetic field with a second polarity directed in substantially the axial direction and configured substantially coaxially with the core at the first end;
at least one reciprocating ferromagnetic body configured substantially coaxially with the core, and not extending completely outside of the core at the second end, adapted to have a second magnetic field in response to the first magnetic field, the body displaceable axially in response to the first and second magnetic fields; and
a transducer unit mechanically connected to the reciprocating body and adapted to convert a displacement of the reciprocating body to a power output.

2. A system according to claim 1, wherein the power output is not less than the first power input.

3. A system according to claim 1, wherein the transducer unit further includes a mechanical energy buffer adapted to non-simultaneously store the power output and to return a second power input.

4. A system according to claim 3, wherein the transducer unit is further adapted to sense the power output, displacement, and velocity of the reciprocating body.

5. A system according to claim 4, wherein the control unit is further adapted to control a plurality of time-varying electrical pulses to provide the first power input based on data indicative from the transducer unit of the sensed power output, displacement, and velocity of the reciprocating body.

6. A system according to claim 5, wherein the control unit is further adapted to control the first power input to maximize the power output.

7. A system according to claim 6, where the stationary body is substantially permanently magnetic.

8. A system according to claim 6, wherein the stationary body is ferromagnetic and the second magnetic field is present in response to the first magnetic field.

9. A system according to claim 8, where the stationary body is a non-powered electromagnet.

10. A system according to claim 6, where the stationary body is a powered electromagnet.

11. A system according to claim 10, where the second field is maintained substantially constant.

12. A system according to claim 10, where the second field is varied in coordination with variations of the first magnetic field.

13. A system according to claim 6, wherein the first electromagnet and the reciprocating ferromagnetic body are fixed in a common housing, and wherein the housing is displaceable axially in response to the first and second magnetic fields.

14. A method of operating a magnetic reciprocating generating system comprising the steps of:
taking at least one first electromagnet having a direction of elongation defining an axial direction, having a first end and a second end, and having an elongated opened core extending from the first end to the second end, the core having an axis of symmetry substantially coaxial with the axial direction;
providing a first power input to the first electromagnet with a control unit and causing the electromagnet to have a time-varying first magnetic field with a first polarity directed in substantially the axial direction;
configuring at least one stationary body substantially coaxially with the core region at the first end, the stationary body having a second magnetic field with a second polarity directed in substantially the axial;
configuring at least one reciprocating ferromagnetic body substantially coaxially with the core, and not extending completely outside of the core at the second end, having a second magnetic field in response to the first magnetic field, the body displaced axially in response to the first and second magnetic fields; and
connecting a transducer unit mechanically to the reciprocating body, the transducer unit converting a displacement of the reciprocating body to a power output.

15. A method according to claim 14, wherein the transducer unit further includes a mechanical energy buffer unit which non-simultaneously stores power output and to return a second power input.

16. A method according to claim 14, wherein the transducer unit further senses the power output, displacement, and velocity of the reciprocating body.

17. A method according to claim 16, wherein a plurality of time-varying electrical pulses is controlled by the control unit to provide the first power input based on data indicative from the transducer unit of the sensed power output, displacement, and velocity of the reciprocating body.

18. A method according to claim 17, wherein the power output is maximized by the control unit controlling the first power input.

19. A method according to claim 18, where the stationary body is substantially permanently magnetic.

20. A method according to claim 18, wherein the stationary body is ferromagnetic and the second magnetic field is present in response to the first magnetic field.
